(19) United States
(12) Patent Application Publication
(10) Pub. No.: US 2023/0091473 A1
(43) Pub. Date: Mar. 23, 2023

(54) Multilayer Diamond Display System and Method

(71) Applicant: AKHAN Semiconductor, Inc., Gurnee, IL (US)

(72) Inventors: Adam Khan, San Francisco, CA (US); Robert Polak, Lindenhurst, IL (US); Priya Raman, San Francisco, CA (US)

(21) Appl. No.: 17/990,368

(22) Filed: Nov. 18, 2022

Related U.S. Application Data
(63) Continuation-in-part of application No. 17/152,709, filed on Jan. 19, 2021, now Pat. No. 11,552,276.
Application No. 17/152,709 is a division of application No. 16/292,280, filed on Mar. 4, 2019, now Pat. No. 10,897,028.
Application No. 16/292,280 is a division of application No. 15/831,184, filed on Dec. 4, 2017, now Pat. No. 10,224,514.
(60) Provisional application No. 62/429,769, filed on Dec. 3, 2016.

(51) Int. Cl. H01L 51/52; H01L 21/02; H01L 31/0232; H01L 51/00

(52) U.S. Cl. CPC H01L 51/5275; H01L 21/02115; H01L 31/0232; H01L 51/0096; H01L 51/5281

(57) ABSTRACT

A multilayer diamond system includes an optically transparent substrate and an optically transparent intermediate layer deposited on the optically transparent substrate. A diamond layer is deposited on the optically transparent intermediate layer and formed from diamond having at least 50% of diamond grains sized between 2 nm and 500 nanometers.

### CROSS-REFERENCE TO RELATED APPLICATIONS

This application is a continuation-in-part of U.S. patent application Ser. No. 17/152,709, filed Jan. 19, 2021, which is a divisional of U.S. patent application Ser. No. 16/292,280, filed Mar. 4, 2019, which is a divisional of U.S. patent application Ser. No.15/831,184, filed Dec. 4, 2017, which claims the benefit of U.S. Provisional Patent Application Ser. No. 62/429,769, filed Dec. 3, 2016, all of which are fully incorporated herein by reference.

### FIELD

This invention is generally related to systems and methods for transparent diamond coating of substrates, and more particularly to a system and method for providing an optically transparent multilayer diamond system suitable for displays, cover glass, protective covers, or optical systems.

### BACKGROUND

Diamond possesses favorable theoretical semiconductor performance characteristics, including the possibility of creating transparent electronics, including those related to consumer electronic component materials, such as display and lens materials. These applications often include more stringent design requirements, such as increased hardness, scratch resistance, and water resistance. However, practical diamond based semiconductor device applications for consumer electronic component materials remain limited.

### SUMMARY

Disclosed herein is a new and improved system and method for a multilayer diamond display system. In accordance with one aspect of the approach, a multilayer diamond display system may include an optical grade silicon substrate, a transparent substrate layer; a titanium dioxide transparent layer, the transparent layer having an index of refraction of 2.35 or greater; and a polycrystalline diamond layer, wherein the transparent layer is between the substrate layer and the polycrystalline diamond layer. In some embodiments, the diamond layer deposited on the optically transparent intermediate layer can be formed from diamond having at least 50% of diamond grains sized between 2 nm and 1 micron.

In another approach, a method of fabricating a multilayer diamond display system may include the steps of selecting a substrate, forming a fused silica and titanium dioxide layer on the substrate, forming a fused silica layer on the fused silica and titanium dioxide layer, forming a titanium dioxide transparent layer on the fused silica layer; and forming a nanocrystalline diamond layer on the titanium dioxide layer.

In another embodiment, a multilayer diamond system includes an optically transparent substrate layer and an optically transparent intermediate layer deposited on the optically transparent substrate. A diamond layer is deposited on the optically transparent intermediate layer and formed from diamond having at least 50% of diamond grains sized between 2 nm and 500 nm. Alternatively, a diamond layer with at least 50% of diamond grains being microcrystalline and sized between 500 nm and 1 micron can be deposited on the optically transparent intermediate layer.

Other systems, methods, aspects, features, embodiments and advantages of the system and method disclosed herein will be, or will become, apparent to one having ordinary skill in the art upon examination of the following drawings and detailed description. It is intended that all such additional systems, methods, aspects, features, embodiments and advantages be included within this description, and be within the scope of the accompanying claims.

### BRIEF DESCRIPTION OF THE DRAWINGS

It is to be understood that the drawings are solely for purpose of illustration. Furthermore, the components in the figures are not necessarily to scale, emphasis instead being placed upon illustrating the principles of the system disclosed herein. In the figures, like reference numerals designate corresponding parts throughout the different views.

FIG. 1 is an exemplary schematic diagram of a fabrication process for a multilayer diamond display system.

FIG. 2 is an exemplary block diagram of an embodiment of a method for fabricating a multilayer diamond display system, such as the display system of FIG. 1.

FIG. 3 is a further exemplary schematic diagram of a fabrication process for a multilayer diamond display system.

FIG. 4 is graphical transmission spectra that may be produced using fabrication processes described herein, such as the processes illustrated in FIG. 2 and FIG. 3.

FIG. 5 is a schematic representation of an embodiment of a display glass multilayer diamond system that may be produced using fabrication processes described herein, such as the processes illustrated in FIGS. 1-3.

FIG. 6 is a table providing comparisons between the prior art materials and systems that may be produced using fabrication processes described herein, such as the embodiment illustrated in FIG. 5.

FIG. 7 is a schematic representation of another embodiment of a multilayer diamond system having interior and exterior diamond multilayers that may be produced using fabrication processes described herein, such as the processes illustrated in FIGS. 1-3.

FIG. 8 is a schematic representation of another embodiment of a multilayer diamond system having a monolithically integrated diamond capacitive layer that may be produced using fabrication processes described herein, such as the processes illustrated in FIGS. 1-3.

### DETAILED DESCRIPTION

The following detailed description, which references to and incorporates the drawings, describes and illustrates one or more specific embodiments. These embodiments, offered not to limit but only to exemplify and teach, are shown and described in sufficient detail to enable those skilled in the art to practice what is claimed. Thus, for the sake of brevity, the description may omit certain information known to those of skill in the art.

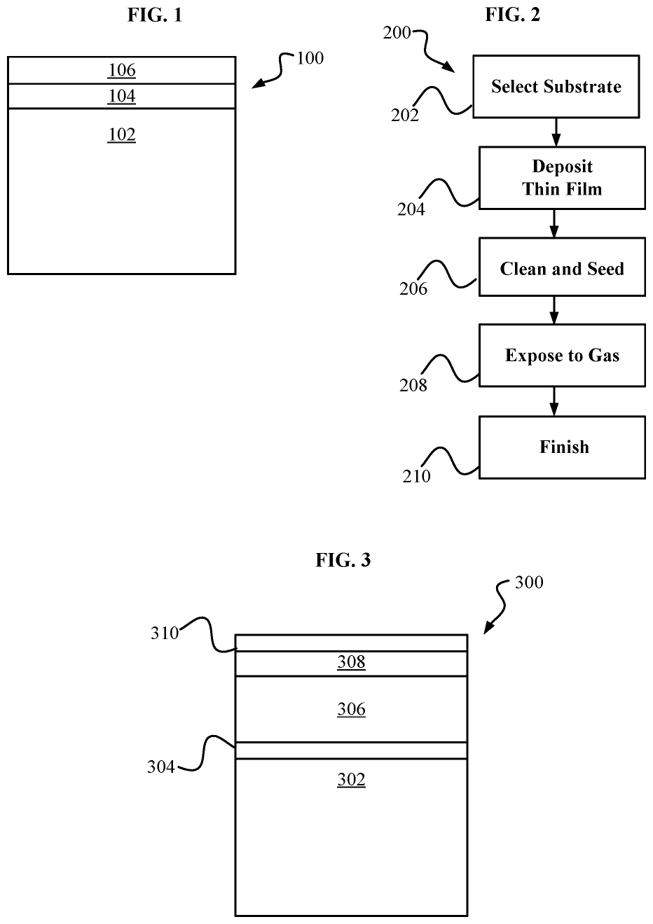

The system and method provided herein allow for a novel diamond based multilayer antireflective coating system and a novel method for infrared optical windows. FIG. 1 shows an exemplary schematic diagram 100 of a fabrication process for a multilayer diamond display system. Diagram 100 includes a substrate material layer 102, a thin film composite layer 104, and a diamond layer 106. Substrate material layer 102 may include a transparent substrate, such as, but not limited to, aluminosilicate glass, for example, Corning Gorilla Glass® 3, commercial glass, for example, BK7, fused silica, quartz, sapphire, indium tin oxide, titanium dioxides, such as, but not limited to, crystalline rutile, in addition to others known to those having ordinary skill in the art. Any of the aforementioned materials, as well as combinations thereof, may be included in substrate layer 102.

The thin film composite layer 104 may include a transparent material with an index of refraction of 2.35 or greater. In one embodiment, titanium dioxide may be deposited on the substrate layer 102 via, for example, but not limited to, physical vapor deposition (PVD) sputtering or reactive ion deposition. In some embodiments, the first thin film layer may have an index of refraction ranging from 2.6 to 2.8. Crystalline titanium dioxide may be used in forming thin film composite layer 104. The thin film layer 104 may include lower refractive index transparent materials to favor transmission at blue, green, and red wavelength ranges. The thin film composite layer 104 may use materials optimized for operating wavelengths for blue light between 440 and 470 nm, green light between 510 and 550 nm, and red light between 600 and 640 nm wavelengths.

The diamond layer 106 may be fabricated by processes including seeding with a nanocrystalline diamond solution mixture. Fabrication of the diamond layer 106 may include acid cleaning, for example, via piranha and ionic clean methods. Fabrication of the diamond layer 106 may include ultrasonic roughening to facilitate more uniform and strong cohesion of growth diamond material. Fabrication of the diamond layer 106 may include chemical vapor deposition techniques, such as, but not limited to Hot Filament and Microwave Plasma methods. In one embodiment, nanocrystalline diamond materials may be formed under vacuum conditions using Methane, Hydrogen, and Argon gas.

FIG. 2 shows an exemplary block diagram of an embodiment of a method 200 for fabricating a multilayer diamond systems, such as, but not limited to, the display system of diagram 100. Method 200 may include a step 202 of selecting a substrate material, such as an optical grade substrate, for example, the substrate of substrate material layer 102.

Method 200 may include a step 204 of depositing a thin film layer, such as, but not limited to thin film composite layer 104. Method 200 may include a step 206 of cleaning a seeding where the surface of the substrate may be acid cleaned, for example, via piranha and ionic clean methods, and ultrasonically roughened to facilitate more uniform and strong cohesion of growth diamond material. In step 206, the substrate may be seeded with a nanocrystalline diamond solution mixture.

Method 200 may include a step 208 of exposing the substrate to gas. Step 208 may include a cooled substrate wafer stage to maintain temperatures at or below 500 degrees Celsius allowing multilayer integration without exceeding stress, softening, and strain limitations of the underlying material layers. The diamond growth process energy is substantially derived from thermally activated filament sources or microwave activated plasma sources. Method 200 may include a step 210 of finishing a multiplayer diamond display system. Step 210 may include surface treatment, surface polishing, and packaging.

FIG. 3 shows another exemplary schematic diagram 300 of a fabrication process for a multilayer diamond display system. Diagram 100 includes a substrate material layer 302, a first thin film composite layer 304, a fused silica layer 306, a titanium dioxide layer 308, and a diamond top layer 310. Substrate material layer 302 may include a transparent substrate, such as those described in regard to substrate material layer 102.

The first thin film composite layer 304 may include fused silica and titanium dioxide producing a refractive index of about 1.75. The titanium dioxide layer 308 may have a refractive index values in the range of 2.6 to 2.8, but with a minimum value of 2.35. The diamond top layer 310 may be formed as described in regard to diamond layer 106.

FIG. 4 shows a graphical transmission spectra 406 that may be produced using fabrication processes described herein, such as the processes illustrated in FIG. 2 and FIG. 3. Graph 400 includes a horizontal axis 402 illustrating light wavelengths, and vertical axis 402 illustrating light wave transmission, through a system fabricated according to the techniques illustrated in FIG. 3, where the system includes: (a) a fused silica/titanium oxide layer, such as first thin film composite layer 304, of 44 nm; (b) a fused silica layer, for example, fused silica layer 306, of 186 nm; (c) a titanium dioxide layer, for example, titanium dioxide layer 308, of 67 nm; and (d) a diamond top layer, for example diamond top layer 310, of 40 nm. In spectra 406 the transmittance at the peak wavelengths are shown to be 89.7%, 86.2% and 87.1% for blue, green and red, respectively, yielding overall transmittance between 88-89%. This high level of transmittance is visually indistinguishable from present mobile and wearable display glass specifications of 92% in this wavelength range, such as standard Corning Gorilla Glass®. Increasing the number of multilayers may increase the transmittance beyond these values. Glass layers may be interspersed with other layers in order to tune transmittance peaks to desired visible wavelengths.

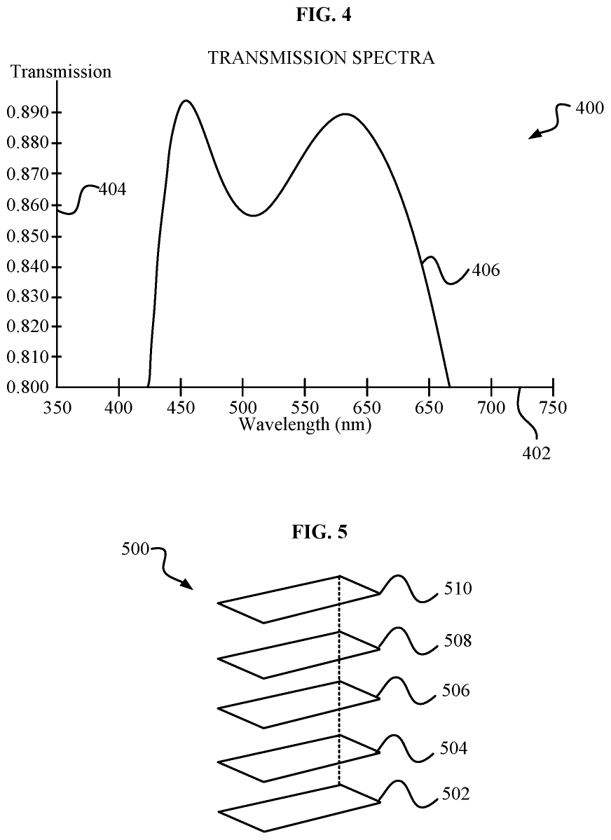

FIG. 5 is a schematic representation 500 of an embodiment of a display glass multilayer diamond system that may be produced using fabrication processes described herein, such as the processes illustrated in FIGS. 1-3. Representation 500 includes a rigid chassis layer 502, a flexible organic light emitting diode layer 504, a capacitive touch layer 506, interior lens glass layer 508, and an exterior glass lens layer 510. The rigid glass layer 502 may be, for example, include aluminum. The capacitive touch layer 506 may be include indium tin oxide and fused silica. The interior lens glass layer 508 may include Gorilla Glass. Exterior glass lens layer 510 may be formed by including systems and methods illustrated in FIGS. 1 and 2. Diamond multilayer structures, such as those illustrated by schematic 500, may provide desirable strength and hardness features which may operate with reduced thermal budget via higher thermal conductivity. Such strength and hardness features are illustrated in table 600, shown in FIG. 6, where features for representation 500 are shown in the bottom row. In table 600, nanocrystalline diamond is approximately 200 nanometers and the fused silica glass is approximately 500 microns.

FIG. 7 is a schematic representation 700 of another embodiment of a multilayer diamond system that may be produced using fabrication processes described herein, such as the processes illustrated in FIGS. 1 3. Representation 700 includes a rigid chassis layer 702, a flexible organic light emitting diode layer 704, a capacitive touch layer 706, and an exterior glass lens layer 708. Representation 700 may allow for the combination, or elimination, of an interior lens, such as interior lens 508 of representation 500. Exterior glass lens layer 708 may be formed by including systems and methods illustrated in FIGS. 1 and 2.

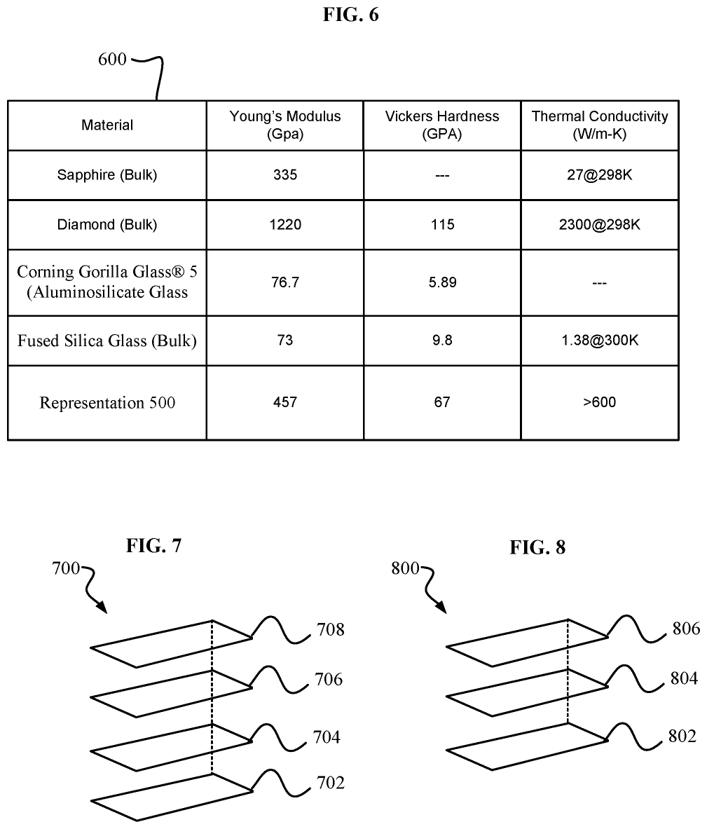

FIG. 8 is a schematic representation 800 of another embodiment of a multilayer monolithically integrated diamond system that may be produced using fabrication processes described herein, such as the processes illustrated in FIGS. 1-3. Representation 800 includes a rigid chassis layer 802, a flexible organic light emitting diode layer 804, and an exterior glass lens layer 506. Exterior glass lens layer 506 may be formed by including systems and methods illustrated in FIGS. 1 and 2. Representation 800 may allow for a multilayer diamond system of less than 0.5 millimeters. In representation 800, the capacitive touch layer may be incorporated as substrate layer. Representation 800 may provide a multilayer monolithically integrated diamond display module with mechanical, optical, and thermal tolerances meeting or exceeding display application demands.

The multilayer diamond display system described, and method 200, may incorporate systems and methods previously disclosed and described in U.S. Patent Publication No. 2013/0026492, by Adam Khan, published on Jan. 31, 2013; U.S. Pat. No. 8,354,290, issued to Anirudha Sumant, et al, on Jan. 15, 2013; U.S. Pat. No. 8,933,462, issued to Adam Khan on Jan. 13, 2015; U.S. Patent Publication No. 2015/0206749, by Adam Khan, published on Jul. 23, 2015; and U.S. Patent Publication No. 2015/0295134, by Adam Khan, et al, published on Oct. 15, 2015, all of which are fully incorporated herein by reference.

In some embodiments, single or multiple diamond films or layers suitable for coating tools can be a component of a multilayer coating or film system applied to a wide variety of substrates. Such diamond layers or films can include multilayer structures that enable or enhance various usages or features, including those that provide for light redirection, interference, cover glass, protective covers, displays, windows, chemical, thermal, or mechanical protection. Applications or components supporting multilayer diamond layers, films, or coatings can include but are not limited to visible or infrared optics, windows, optical waveguides, semiconductors, semiconductor coatings, and rugged or durable coatings for electronics, manufacturing, or tooling. Other applications for diamond multilayer coatings can include use in biological substrates or medical devices, or use in batteries, fuel cells, electrochemical systems, chemo-sensors, general sensing, or integration with other advanced materials.

As used in this disclosure, the terms “layer”, “film”, and “coated” can be interchangeably used, and refer to thin deposited, chemically formed, grown materials, or otherwise situated materials on a substrate that can itself be a layer, film or coating. Diamond layers or films can include intrinsic diamond, diamond-like material, or diamond with small amounts of graphite or other materials. Diamond lattice structure can be selectively modified and can include provision of varying sp2/sp3 carbon materials positioned through selective seeding or etch, nucleation or growth process parameters including gas composition, pressure, and temperature among other parameters, selective laser annealing, particle bombardment or doping, or use of laser pulse to grow diamond. Modification of diamond layers or films by oxygen termination, hydrogen termination, chlorine or fluorine functionalization are additional embodiments.

In some embodiments, diamond layers intended for sensing, waveguide, or electronic usage can benefit from doping, including p-doping and n-doping. Dopants including but not limited to P, B, Li, or H can also be added. In some embodiments, introducing a minimal amount of acceptor dopant atoms to a diamond lattice can additionally create ion tracks. The creation of the ion tracks may include creation of a non-critical concentration of vacancies, for example, less than 10²²/cm³ for single crystal bulk volume, and a diminution of the resistive pressure capability of the diamond layer. For example, acceptor dopant atoms can be introduced using ion implantation at approximately 80 degrees Kelvin (K) to 600 K. In other embodiments, acceptor dopant atoms can be introduced using ion implantation at 293 to 298 degrees Kelvin in a low concentration. The acceptor dopant atoms may be p-type acceptor dopant atoms. The p-type dopant may be, but is not limited to, boron, hydrogen and lithium. In one embodiment, ion tracks that act as a ballistic pathway for introduction of larger substitutional dopant can be created. This allows placement of substitutional dopant atoms into the diamond lattice through the ion tracks. For example, larger substitutional dopant atoms using ion implantation placed at or below approximately 78 degrees K for energy implantation at less than 500 keV. Implanting below 78 degrees K can allow for the freezing of vacancies and interstitials in the diamond lattice, while maximizing substitutional implantation for the substitutional dopant atoms. The larger substitutional dopant atoms may be for example, but is not limited to, phosphorous, nitrogen, sulfur and oxygen. Such larger substitutional dopant atoms may be introduced at a much higher concentration than the acceptor dopant atoms. The higher concentration of the larger substitutional dopant atoms may be, but is not limited to, approximately 9.9×10¹⁷/cm³ of phosphorous and a range of 8×10′⁷ to 2×10¹⁸/cm³. As another example, nitrogen can be implanted at a concentration of up to 9×10′⁸/cm³.

In some embodiments, a diamond layer can have a sp2 concentration of less than 20% by diamond layer volume. In other embodiments, a diamond layer can have a grain orientation at least 80% in either the <111>or <100>crystalline direction. In still other embodiments, a highly oriented diamond film can include differing crystal orientations in selected region or layers, with <111>and <100>crystalline direction respectively predominating.

Properties of diamond in the multilayer coating or film system can be measured and characterized using Raman spectroscopy. Cubic diamond has a single Raman-active first order phonon mode at the center of the Brillouin zone. The presence of sharp Raman lines allows cubic diamond to be recognized against a background of graphitic or other carbon crystal types. Small shifts in the band wavenumber can indicate diamond composition and properties. In some embodiments, the full width half maximum (FWHM) obtained from Raman characterization for the diamond layers or films formed as indicated in this disclosure can be between 5-15. In other embodiments, a diamond layer can have a Raman spectrographic signature of diamond (approximately 1332 nm) at least or greater than 0.5:1 as compared to peak Graphitic Band (1400-1600 nm) by Raman Analysis. In other embodiments, a diamond layer can have physical properties such as Vickers hardness measured by nanoindentation of at least 12 Gigapascal or greater than 20 Gigapascal. In other embodiments, a diamond layer can be measured to exert a compressive stress less than 50 Gigapascal.

In some embodiments, substantially monocrystalline diamond can be formed on at least a portion of a substrate. In other embodiments, polycrystalline diamond or diamond-like material can be formed on all or at least a portion of the substrate. In some embodiments, polycrystalline diamond grains sized to be less than 1 micron (1000 nanometers) and greater than 500 nanometers can be used. In other embodiments, polycrystalline diamond or diamond-like material can include ultrananocrystalline grain sizes (2-10 nanometers), nanocrystalline grain sizes (10-500 nanometers), or microcrystalline grain sizes (500 nanometers or greater). In some embodiments, diamond grain size can include a range of grain sizes, including larger and smaller grains. In some embodiments, a diamond layer can be formed to have grains of less than 1 microns. In some embodiments, grain size can differ by greater or less than 50%, 100%, 200% or 500% of mean diamond grain size. In other embodiments, diamond grain size can be maintained to within 50%, 20%, or 10% of mean grain size. In some embodiments, 50%, 60%, 80%, or 90% of the diamond grains can be sized between 50 and 500 nanometers. In some embodiments, a diamond layer can be formed from at least 90% nanocrystalline diamond and have diamond grains sized between 2 nanometers and 500 nanometers. In some embodiments, a diamond layer can be formed from at least 90% microcrystalline diamond and have diamond grains sized between 500 nanometers and 1000 nanometers. In other embodiments, diamond grains can be sized between 500 nanometers and 1000 nanometers. In other embodiments, 90% of the diamond grains can be sized between 200 and 300 nanometers.

In some embodiments, diamond grain size in a diamond layer can be controlled to improve particular optical, thermal, or mechanical characteristics of a diamond layer containing multilayer coating or film system. For example, optical transparency can be increased by use of ultrananocrystalline or nanocrystalline sized grains that are sized between 2 nanometers and 30 nanometers.

Diamond layer thickness in some embodiments can be selected to be between 200 nanometers and 100 microns. Typically diamond grain size will be 50% or less of diamond layer thickness. In some embodiments useful for optical coatings, diamond layer thickness will be between 20 and 200 nanometer. For example, in one embodiment a glass or other transparent material can be coated with a diamond film having a thickness between 10 nanometer and 1000 nanometer thickness. When used in optically transmissive systems, the diamond film provides transmission of light through the glass substrate and the diamond film at 550 nanometer wavelength is in excess of 0.60, 0.70, 0.80 or 0.90, the transmission of light between 350 nanometer and 450 nanometer wavelength is less than 0.60, 0.70, 0.80 or 0.90, and the transmission of light between 750 nanometer and 850 nanometer of less than 0.60, 0.70, 0.80 or 0.90. In other embodiments of optically transmissive systems, the diamond film provides transmission of light through the glass substrate and the diamond film with a transmissivity in excess of 0.60, 0.70, 0.80 or 0.90 at wavelengths ranging between 500 and 600 nanometers, 530 and 570 nanometers, or 540 and 560 nanometers. In some embodiments a glass or other transparent material can be coated with a diamond film that provides haze of less 20% for thick diamond layers (e.g. ranging from 1 micron to 10 microns), less 10% for thin diamond layers (e.g. ranging from 200 nanometers to 1000 nanometers), and less 5% for very thin diamond layers (e.g. below 200 nanometers). In other embodiments, thicker diamond layer coatings of up to 10 microns can be used to improve mechanical, frictional, or thermal characteristics.

Diamond layers can have a substantially uniform thickness over all or defined portions of a surface or substrate. In other embodiments, thickness can vary over portions of a surface or substrate. In some embodiments diamond layers can be conformal when extending over cavities, depressions, or protrusions in a substrate or surface. In some embodiments, diamond layers can steadily thin or thicken away from one or more positions on a substrate. In some embodiments, thinning or thickening can be less than 20%, 10%, 6%, or 3% of diamond layer thickness over the substrate.

Multiple diamond layers distinguished by composition, crystal structure, dopants, grain size, or grain size distribution can be a part of a multilayer coating or film system applied to a substrate. Distinct diamond layers can be layered on top of diamond layers or non-diamond materials. In certain embodiments, physical parameters of diamond layers can continuously or semi-continuously change vertically or laterally through the layer.

Diamond layers can be deposited and optionally structured using selective seeding techniques. Seed layers can include use of selective deposition or etched seed areas. In some embodiments, nanocrystalline diamonds can be directly deposited or deposited in a solution.

Diamond layers, whether grown with or without seeding, can be deposited on various substrates, including but not limited to glass, ceramics, oxides, or metals. For example, a substrate can be a silicon oxide materials, SiO2, fused silica, quartz, sapphire, gallium nitride (GaN), gallium arsenide (GaAs), and refractory metals. In addition, the substrate materials may include carbon-carbon bonding allows integration with other materials such as SiC, graphene, carbon nano tubes (CNT), as well single crystal, polycrystalline diamond materials, and combinations of the materials. Substrates can be transparent, semi-transparent, or opaque at selected wavelengths or wavelength ranges. For example, in some embodiments, a substrate can have a transmissivity of 80% or greater at one of optical or infrared wavelengths. In some embodiments, a diamond layer has a transparency of greater than about 80%, for example, 81%, 82%, 83%, 84%, 85%, 86%, 87%, 88%, 89%, 90%, 91%, 92%, 93%, 94% or about 95% inclusive of all ranges and values therebetween. In particular embodiments, the diamond layer has a thickness, for example, between 30 nanometers to about 150 nanometers (e.g., about 30 nanometers, 40 nanometers, 50 nanometers, 60 nanometers, 70 nanometers, 80 nanometers, 90 nanometers, 100 nanometers, 110 nanometers, 120 nanometers, 130 nanometers, 140 nanometers, or about 150 nanometers inclusive of all ranges and values there between). Furthermore, the diamond layer can have a root mean square (RMS) roughness of less than 7 nanometers. In some embodiments, the diamond layer can have an RMS roughness of less than 50%, 40%, 30%, 20%, or 10% of the film thickness. In some embodiments, the diamond layer can have an RMS roughness of less than 20% of the diamond layer thickness.

Diamond deposition can be by any process such as, but not limited to, chemical vapor deposition (CVD) and physical vapor deposition (PVD). A wide variety of embodiments of vapor deposition method can be used. Examples of vapor deposition methods include hot filament CVD, microwave CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, cathodic arc, and the like.

In some embodiments, a thin diamond film can be deposited at relatively low temperatures of less than 600, 500, or 450 degrees Celsius using an activation medium like plasma, argon gas and a carbon source, such as methane. In other embodiments, deposition can be at temperatures between 300 and 600 degrees Celsius. In other embodiments, deposition can be at temperatures between 375 and 425 degrees Celsius. Advantageously, as compared to conventional 700-800 degree Celsius temperatures for diamond film growth, such low temperatures greatly reduce thermal effects, including thermal degradation or warping, and allow for a greater variety of substrates to be used.

In some embodiments, various processes can be used to improve diamond or other film quality. For example, a substrate can be subjected to dry and/or wet chemical cleaning, including but not limited to strong or weak acid and/or base cleaning, solvent cleaning, ultrasonic agitation, spray coating, plasma cleaning, ultraviolet (UV) and ozone, tetramethyl ammonium hydroxide, or any suitable combination of cleaning processes. Plasma cleaning can include subjecting a substrate to plasma derived from argon and/or oxygen in various concentrations. Ozone may be chemical ozone, derived from heated sources, or both.

In some embodiments, before deposition of a diamond or diamond like film, a substrate can be treated by sputtering, evaporation, atomic layer deposition (ALD), chemical vapor, plasma, thermal or form of deposition of one or more of materials including but limited to oxides and nitride dielectric materials, oxides of metals such as titanium, indium, tin, zinc, or combinations, oxides of graphene such as graphene oxide, reduced fluorinated graphene oxide, oxides of silicon, titanium, or aluminum, nitrides of aluminum, silicon, titanium, boron, and metals such as tungsten or titanium. Advantageously in some embodiments this can reduce coefficient of thermal expansion differences, reducing interlayer and subsurface stress, and allow for tune coloration, as well as optical losses attributable to haze or reflectance.

In some embodiments, for metal deposited via sputter deposition, power levels may can be adjusted, and shutter opening times can vary to achieve the target thickness uniformly across the display glass surface. For oxides and nitrides deposited via ALD, thin films may utilize lower temperature (including temperatures less than or equal to 600° C.) and/or crystalline structure to achieve optimal integration with subsequent diamond layer.

In some embodiments, a substrate may be subjected to surface functionalization treatment steps. This can include surface functionalization by wet chemistry that includes spray coating, biased spray coating, ultrasonic spray coating, volume by ultrasonic agitation of solvent and ketone mixtures, including but not limited to methanol, acetone, isopropyl alcohol, ethanol, butanol, or pentanol. The functionalized surface can include hydrocarbon chains, hydroxyl bonds, oxygen termination, or other suitable chemically active materials.

To encourage growth of diamond layers or films with selected grain sizes or in defined areas, a substrate can be seeded with diamond crystal particulates ranging in size from nanometer to microns. In some embodiments, seed size can range from 5 to 50 nanometers. Seeds can be functionalized, or can have a positive, negative, or neutral zeta potential. The seed crystals may be in a solvent, dimethyl sulfoxide, oil, photoresist, deionized water, a combination or similar types of suspension or matrix. Substrate coverage with diamond crystal seeds can be uniform 105-1013 grains per square centimeter, non-uniform, or localized in selected areas using masks, selective spraying, electrospraying, ultrasonic spraying, or other form of spatially localized application. In some embodiments seeds of differing sizes and characteristics can be used.

Seeded substrates can be loaded into a chemical vapor deposition (CVD) system under low vacuum pressures in the range of 30 mTorr to 300 Torr. A CVD system can be thermal, microwave, or a combination of thermal and microwave configurations. Thermal CVD can include hot filament, hot wire, optical beam, or other, while microwave can include either or both 915 MHz and 2.45 GHz systems. The substrate is then exposed to ions generated from a thermal or microwave source with originating source and reactant feed gases comprising one or more of the following: hydrogen, argon, acetylene, acetone, oxygen, methane, carbon monoxide, carbon dioxide, or other carbon containing source. In one embodiment the diamond may by be single crystal diamond. In another embodiment the diamond may be polycrystalline diamond. In one embodiment nanocrystalline sized diamond can be utilized. The deposition process may be further modified through the use of variable pressures, positive and/or negative stage biasing, stage heating and/or cooling, or control of stage to plasma source distance. The reactant and initiator gas volumes, ratios, and flow rates, temperature at the gas inlet, substrate temperature, intermediate electric field from energy source to substrate surface, and chamber pressure may be adjusted such that grown diamond layers or films exert stress in compressive rather than tensile form. In some embodiments, this allows display glass layers to be held under compression, increasing display glass toughness and strength. Further, the thermal decomposition and ionic energy of the source gases may favor diamond properties through control of CH hydrocarbon radicals versus C₂ (dimer) hydrocarbon radical volumes.

In some embodiments, a deposited diamond film can be further cleaned, and exposed to a two dimensional top layer material, such as reduced fluorinated graphene oxide, graphene, graphene oxide, or similar materials. In some embodiments this provides for superhydrophobicity or oleophobicity without significant degradation to diamond film properties, including optical transmissivity and/or hardness. In one embodiment, graphene oxide may come from a chemical suspension of multilayer graphene oxide and spun on to the diamond film, and either wet chemically or dry chemically (plasma) reduced through inclusion of fluorine atoms into the material, in substitution to oxygen.

In some embodiments, a diamond layer coating a substrate can be subjected to further chemical and mechanical treatment such as reactive ion etching, which may produce bulk planarized uniform diamond layers or films of the desired thickness. In one embodiment the RIE (Reactive Ion Etching) uses CHF₃ and CF₄ at a ratio of 3:1. Further planarization and/or polishing steps may be utilized to achieve desired flatness and surface finishing.

Diamond layers or films such as described herein can be deposited on a wide variety of substrate types and shapes. Substrates can include Si, SiC, SiSiC, amorphous silicon, diamond-like carbon, metal-doped oxides glass materials; polymeric materials; ceramics including quartz, sapphire, and the like; metals and metal alloys, or mixtures and combinations thereof. In some embodiments, substrates can include aluminosilicate glass, for example, Corning Gorilla Glass®, borosilicate glass, commercial glass, for example, BK7, fused silica, quartz, sapphire, indium tin oxide, titanium dioxides, such as, but not limited to, crystalline rutile.

In some embodiments, substrate form and composition can be altered by maskless or mask etching, additive or subtractive photoresist etching, or direct mechanical cutting, drilling, or grinding. In still other embodiment, laser sintering or other additive manufacturing techniques can be used to build up a substrate into a desired form. In some embodiments, doping, sputtering, evaporation, atomic layer deposition (ALD), chemical vapor, plasma, thermal or other form of deposition can be used to deposit various materials previously discussed with respect to preparation for processing diamond layers or films. In some embodiments, a deposited diamond layer can act as a support for additional diamond or non-diamond layers or films.

In some embodiments, substrates can be flat, curved, smoothly continuous, and include sidewalls, edges, beveled edges, or curved edges. A surface can be of one distinct composition or can include multiple compositions. Substrate embodiments can also include single or multiple cavities, indentations, or can be channels defined therein, as well as protrusions such as pillars and projections. In other embodiments, substrates can include burls, mesas, bumps, pins, islands, irregular or regular surface structures, nano-projections, and the like. In accordance with an embodiment, cavities or protrusions can be selected to have predetermined size, spacing, and composition, while in other embodiments size, spacing, and composition can be random or semi-random.

While substrates can be mechanically rigid and have millimeter or greater thicknesses, in some embodiments a substrate includes other thin diamond layers, or thin layers of a metals, ceramics, glasses, or other compositions. Thickness of such layers can be less than 1 mm, 1 micron, or 100 nanometers. Such layers can act as intermediate or buffer layers, and can improve optical, electrical, thermal, or mechanical properties of the multilayer structure. In some embodiments, substrates or intermediate layers can be transparent and include one or more of metals (e.g. tungsten or titanium); ceramics, or glass (e.g. aluminosilicate or borosilicate). In some embodiments, substrates or an optically transparent intermediate layer can include one or more of indium tin oxide, aluminum oxide, titanium oxides including but not limited to titanium dioxide, magnesium oxide, silicon dioxide, and hafnium oxide. In other embodiments, substrates or an optically transparent intermediate layer can include one or more of nitrides of aluminum, silicon, titanium, or boron. Layers can also include but are not limited to carbon film formed of diamond-like carbon (DLC), amorphous carbon or nano-crystal diamond (NCD), or a metal film made of molybdenum, titanium, tungsten, chromium or copper, or a ceramic film formed of SiC, TiC, CrC, WC, BN, B4C, Si3N4, TiN, CrN, SiCN, or BCN. The thickness of an intermediate or buffer layer can range from 10 nanometers to 100 microns, when thickness of the diamond film ranges from 10 nanometers to 1000 nanometers.

As will be understood, the described diamond layers, substrates, and thin films of non-diamond materials can include various embodiments, characteristics, and combinations, including but not limited to the following additional examples:

Example 1—In a first example, a transparent diamond layer can be continuously and conformally coated over a transparent glass substrate to act as an optically clear protective coating suitable for smart phones, tablets, or laptops. For example, a substantially uniform 70-110 nanometers thick nanocrystalline diamond film having a grain size ranging between 20 to 70 nanometers can be deposited on a conductive indium tin oxide (ITO) film that is deposited on the transparent glass substrate. Optionally a hydrophobic coating or additional diamond coating doped or functionalized to support a hydrophobic or oleophobic coating can be deposited on the substantially uniform 70-110 nanometers thick nanocrystalline diamond film. In some embodiments, the grain size can be diamond grains range from 5 nanometers to 50 nanometers The glass substrate can be chemically cleaned using acetone, followed by cleaning using UV ozone. Alternatively, float glass or similar substrates can be acid cleaned to remove tin or other metallic coatings. In some embodiments the glass surface can be functionalized to include hydrocarbon chains derived from solvent breakdown while drying.

A conventional HF CVD reactor with tungsten, tantalum, or rhenium filaments can be used. Filament diameter, spacing, and number can be adjusted to provide best results. In one embodiment, filament diameter 0.12 to 0.5 mm, spacing can be 8 to 30 mm, and between 7 to 28 filaments used. Chambers can be spherical, rectangular, or cylindrical. In one embodiment, a cylindrical sphere can be sized to have a volume between 100 to 200 liters, with diameter between 30 to 150 centimeters.

The reactor can include a stage capable of supporting heating or cooling of the substrate. In some embodiments the reactor stage can be set to provide a substrate deposition temperature between 500 and 600 C. At these temperature ranges, diamond layer deposition rates can be between 10 to 100 nanometers per hour.

Precursor gases including methane, hydrogen, oxygen, and argon can be introduced into the chamber at a pressure of 10-15 Torr. In particular, addition of less than 1% oxygen can lower required temperature to maintain an expected deposition rate, and oxygen will preferentially etch sp2 deposited areas. Methane concentration can be between 0.5 to 5 percent of total gas volume. Hydrogen concentration can be between 60 to 90 percent of total gas volume. Argon concentration can be between 10 to 40 percent of total gas volume.

To ensure consistent grain size, the substrate can be coated with diamond seeds dispersed in a dimethyl sulfoxide (DMSO) or other solvent solutions including but limited to ethanol, methanol, IPA, and acetone. In some embodiments, 5 to 50 nanometer grain sizes can be used.

In some embodiments, the diamond film is continuous and conformal over the substrate.

Further, the diamond film can have a FWHM of 5-7 and an sp2 concentration of less than 20% by volume, a grain orientation of at least 80% in the <111>crystalline direction, a Raman spectrographic signature of diamond (approximately 1332 nm) of between 0.7:1 and 1.2:1 as compared to peak Graphitic Band (1400-1600 nm) by Raman Analysis, a Vickers hardness of between 20 and 60 Gigapascal, and with transmission of light through the glass substrate and the diamond film at 550 nanometer wavelength is in excess of 0.70, a haze of less than 5%.

Example 2—In a second example, a substrate can be coated with a substantially uniform 100-2000 nanometers thick nanocrystalline diamond layer or film having a grain size ranging between 100 to 2000 nanometers. In one embodiment, the 100-2000 nanometers thick nanocrystalline diamond film can be further etched, with additional layers or films being selectively applied to fill in etched diamond and support formation of waveguides for data transfer. In some embodiments, the deposited grain size can include diamond grains ranging from 5 nanometers to 50 nanometers.

The reactor can include a stage capable of supporting heating or cooling of the substrate. In some embodiments the reactor stage can be set to provide a substrate deposition temperature between 500 and 800 C. At these temperature ranges, diamond layer deposition rates can be between 10 to 200 nanometers per hour.

The substrate can be coated with diamond seeds dispersed in a DMSO or other solvent solutions including but limited to ethanol, methanol, IPA, and acetone. In some embodiments, 5 to 15,000 nanometer grain sizes can be used, with larger grains typically being reduceable in size by sonication or other processing steps. Various grain sizes or grain size ranges can be used in some embodiments, including co-deposited small and large grain sizes. In some embodiments, the seeds are deposited in a manner that ensures that the film is continuous and conformal over the substrate.

In some embodiments, the diamond layer or film can have a Young's modulus in excess of 80 Gigapascal.

Example 3—In a third example, a transparent substrate can be coated with multiple layers, including diamond layers, ceramic layers, or metal layers. In some embodiments, a substantially uniform 5-50 nanometers thick nanocrystalline diamond layer or film having a grain size ranging between 5 to 50 nanometers can be deposited.

The reactor can include a stage capable of supporting heating or cooling of the substrate. In some embodiments the reactor stage can be set to provide a substrate deposition temperature between 500 and 600 C. At these temperature ranges, diamond layer deposition rates can be between 10 to 100 nanometers per hour.

In the foregoing description, reference is made to the accompanying drawings that form a part thereof, and in which is shown by way of illustration specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The foregoing detailed description is, therefore, not to be taken in a limiting sense.

Reference throughout this specification to “one embodiment,” “an embodiment,” “one example,” or “an example” means that a particular feature, structure, or characteristic described in connection with the embodiment or example is included in at least one embodiment of the present disclosure. Thus, appearances of the phrases “in one embodiment,” “in an embodiment,” “one example,” or “an example” in various places throughout this specification are not necessarily all referring to the same embodiment or example. Furthermore, the particular features, structures, databases, or characteristics may be combined in any suitable combinations and/or sub-combinations in one or more embodiments or examples. In addition, it should be appreciated that the figures provided herewith are for explanation purposes to persons ordinarily skilled in the art and that the drawings are not necessarily drawn to scale.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

We claim:

1. A multilayer diamond system, comprising:
an optically transparent substrate;
an optically transparent intermediate layer deposited on the optically transparent substrate; and
a diamond layer deposited on the optically transparent intermediate layer and formed from diamond having at least 50% of diamond grains sized between 2 nm and 500 nanometers.

2. The system of claim 1, wherein the substrate is at least one of silicon oxide, glass, quartz, and sapphire.

3. The system of claim 1, wherein at least one of the substrate and optically transparent intermediate layer is a metal.

4. The system of claim 1, wherein at least one of the substrate and optically transparent intermediate layer is a ceramic.

5. The system of claim 1, wherein at least one of the substrate and optically transparent intermediate layer is a glass.

6. The system of claim 1, wherein at least one of the substrate and optically transparent intermediate layer comprises at least one of tungsten and titanium

7. The system of claim 1, wherein at least one of the substrate and optically transparent intermediate layer comprises indium tin oxide, aluminum oxide, titanium oxides including but not limited to titanium dioxide, magnesium oxide, silicon dioxide, and hafnium oxide.

8. The system of claim 1, wherein at least one of the substrate and optically transparent intermediate layer comprises nitrides of aluminum, silicon, titanium, or boron.

9. The system of claim 1, wherein at least one of the substrate and optically transparent intermediate layer comprises at least one of aluminosilicate and borosilicate glass.

10. The system of claim 1, wherein the diamond layer comprises a substantially uniform 70-150 nanometers thick diamond film having at least 50% of diamond grains sized between 10 to 100 nanometers.

11. The system of claim 1, wherein the substrate has a dimension of at least one centimeter.

12. The system of claim 1, wherein the substrate further comprises a sidewall coated with the diamond layer.

13. The system of claim 1, wherein the diamond layer is deposited on the substrate at a temperature below 600 degrees Celsius.

14. The system of claim 1, wherein transmission of light through the optically transparent substrate layer, the diamond layer, and the optically transparent intermediate layer at 550 nanometer wavelength is in excess of 0.80.

15. A method for manufacturing a multilayer diamond system, comprising:
providing an optically transparent substrate;
depositing an optically transparent intermediate layer on the optically transparent substrate; and
depositing a diamond layer on the optically transparent intermediate layer, with the diamond layer formed from diamond having at least 50% of diamond grains sized between 2 nm and 500 nanometers.

16. The method for manufacturing a multilayer diamond system of claim 15, wherein the substrate is at least one of silicon oxide, glass, quartz, and sapphire.

17. The method for manufacturing a multilayer diamond system of claim 15, wherein at least one of the substrate and optically transparent intermediate layer is a metal.

18. The method for manufacturing a multilayer diamond system of claim 15, wherein at least one of the substrate and optically transparent intermediate layer is a ceramic.

19. The method for manufacturing a multilayer diamond system of claim 15, wherein at least one of the substrate and optically transparent intermediate layer is a glass.

20. The method for manufacturing a multilayer diamond system of claim 15, wherein at least one of the substrate and optically transparent intermediate layer comprises at least one of tungsten and titanium

21. The method for manufacturing a multilayer diamond system of claim 15, wherein at least one of the substrate and optically transparent intermediate layer comprises indium tin oxide, aluminum oxide, titanium oxides including but not limited to titanium dioxide, magnesium oxide, silicon dioxide, and hafnium oxide.

22. The method for manufacturing a multilayer diamond system of claim 15, wherein at least one of the substrate and optically transparent intermediate layer comprises nitrides of aluminum, silicon, titanium, or boron.

23. The method for manufacturing a multilayer diamond system of claim 15, wherein at least one of the substrate and optically transparent intermediate layer comprises at least one of aluminosilicate and borosilicate glass.

24. The method for manufacturing a multilayer diamond system of claim 15, wherein the diamond layer comprises a substantially uniform 70-150 nanometers thick diamond film having at least 50% of diamond grains sized between 10 to 100 nanometers.

25. The method for manufacturing a multilayer diamond system of claim 15, wherein the substrate has a dimension of at least one centimeter.

26. The method for manufacturing a multilayer diamond system of claim 15, wherein the substrate further comprises a sidewall coated with the diamond layer.

27. The method for manufacturing a multilayer diamond system of claim 15, wherein the diamond layer is deposited on the substrate at a temperature below 600 degrees Celsius.

28. The method for manufacturing a multilayer diamond system of claim 15, wherein transmission of light through the optically transparent substrate layer, the diamond layer, and the optically transparent intermediate layer at 550 nanometer wavelength is in excess of 0.80.
